(19) United States
(12) Patent Application Publication
(10) Pub. No.: US 2011/0114146 A1
(43) Pub. Date: May 19, 2011

(54) UNIWAFER THERMOELECTRIC MODULES

(75) Inventor: Matthew L. Scullin, (US)

(73) Assignee: Alphabet Energy, Inc., San Francisco, CA (US)

(21) Appl. No.: 12/943,134

(22) Filed: Nov. 10, 2010

Related U.S. Application Data
(60) Provisional application No. 61/261,174, filed on Nov. 13, 2009.

(51) Int. Cl. H01L 35/30; H01L 21/329

(52) U.S. Cl. 136/205; 438/54; 257/E21.351

(57) ABSTRACT

A uniwafer device for thermoelectric applications includes one or more first thermoelectric elements and one or more second thermoelectric elements comprising respectively a first and second patterned portion of a substrate material. Each first/second thermoelectric element is configured to be functionalized as an n-/p-type semiconductor with a thermoelectric figure of merit ZT greater than 0.2. The second patterned portion is separated from the first patterned portion by an intermediate region functionalized partially for thermal isolation and/or partially for electric interconnecting. The one or more first thermoelectric elements and the one or more second thermoelectric elements are spatially configured to allow formation of a first contact region and a second contact region respectively connecting to each of the one or more first thermoelectric elements and/or each of the one or more second thermoelectric elements to form a continuous electric circuit.

### CROSS-REFERENCES TO RELATED APPLICATIONS

This application claims priority to U.S. Provisional Patent Application No. 61/261,174, filed Nov. 13, 2009, entitled “THERMOELECTRIC MODULES MADE FROM A SINGLE WAFER OF MATERIAL” by inventor Matthew L. Scullin, incorporated by reference herein for all purposes.

### BACKGROUND OF THE INVENTION

The present invention relates generally to thermoelectric devices. More particularly, the present invention provides a uniwafer thermoelectric device and a method for making the same. Merely by way of example, embodiments of the invention provide a method to achieve substantial reduction of process complexity, number of steps, and cost of thermoelectric module assembly that would entail the transformation of a single wafer of material into an entire thermoelectric device, but it would be recognized that the invention may have other device configurations.

Thermoelectric materials are ones that, in the solid state and with no moving parts, can, for example, convert an appreciable amount of thermal energy into electricity in an applied temperature gradient (e.g., the Seebeck effect) or pump heat in an applied electric field (e.g., the Peltier effect). Solid-state heat engines' potential applications are numerous, including the generation of electricity from various heat sources whether primary or waste, and the cooling of spaces or objects such as microchips and sensors. Interest in the use of thermoelectric devices that comprise thermoelectric materials has grown in recent years in part due to advances in nano-structured materials with enhanced thermoelectric performance (e.g., efficiency, power density, or “thermoelectric figure of merit” ZT, where ZT is equal to S² σ/k and S is the Seebeck coefficient, σ the electrical conductivity, and k the thermal conductivity of the thermoelectric material) and also due to the heightened need both for systems that either recover waste heat as electricity to improve energy efficiency or cool integrated circuits to improve their performance.

To date, thermoelectrics have had limited commercial applicability due to the poor cost performance of these devices compared to other technologies that accomplish similar means of energy generation or refrigeration. Where there are no other technologies as suitable as thermoelectrics for lightweight and low footprint applications, thermoelectrics have nonetheless been limited by their prohibitively high costs. Important in realizing the usefulness of thermoelectrics in commercial applications is the manufacturability of devices that comprise high-performance thermoelectric materials (e.g., modules). These modules are preferably produced in such a way that ensures, for example, maximum performance at minimum cost. The thermoelectric materials in presently available commercial thermoelectric modules are generally comprised of bismuth telluride or lead telluride, which are toxic, difficult to manufacture with, and expensive to procure and process, With a strong present need for both alternative energy production and microscale cooling capabilities, the driving force for highly manufacturable, low cost, high performance thermoelectrics is growing.

Some conventional thermoelectric modules comprise semiconductor thermoelectric materials such as bismuth telluride (Bi₂Te₃), lead telluride (PbTe), and silicon germanium (SiGe). In addition, other conventional modules have been made that comprise alloys such as chalcogenides, skutterudites, and clathrates. These materials pose difficulties in the creation of cost-effective thermoelectric systems because of the difficulty associated with the synthesis of these semiconductors and their subsequent manufacturing into thermoelectric modules, which includes soldering and adhering metal contact layers to the thermoelectric semiconductors. Limited infrastructure exists to process materials of this nature in this fashion after decades of research and development, and fundamental limits on their scalability can also limit the growth of this infrastructure.

Thermoelectric devices, or modules, require two thermoelectric materials: one an n-type semiconductor, the other p-type. Many times these two semiconductors can be entirely different materials rather than merely two complementarily doped forms of the same semiconductor. It is therefore necessary in such an instance to establish synthesis, soldering, metallization, assembly, and other manufacturing techniques for two material systems rather than one.

Thermoelectric n- and p-type semiconductors are generally grown as crystalline ingots separately before being diced into thermoelectric legs, contacted electrically, and assembled in a refrigeration (e.g., Peltier) or energy conversion (e.g., Seebeck) device. This often involves bonding the thermoelectric legs to metal contacts in a configuration that allows an electrically series connection while remaining thermally in parallel so as to establish a temperature gradient across all the legs simultaneously. For energy conversion, these devices or modules are usually placed in a temperature gradient so as to generate electricity, and for Peltier cooling, a current is often induced in them to pump heat.

Compact, solid state thermoelectric generators or coolers offer many benefits over larger thermodynamic systems that accomplish similar tasks. However, their applicability has been limited due to the above considerations. Costs associated with the processing and assembly of materials such as Bi₂Te₃ and PbTe often limit the use of thermoelectrics in all but a handful of applications. As such, a need exists for a method to simplify the production of thermoelectric modules from thermoelectric materials. The elimination of assembly and the integration of all the components of a thermoelectric module into a single set of processing steps can simplify the production of thermoelectric modules, and bring their cost down by over 80%.

From the above, it can be seen that an improved thermoelectric module and a method for manufacturing the same are desired.

### BRIEF SUMMARY OF THE INVENTION

The present invention relates generally to thermoelectric devices. More particularly, the present invention provides a uniwafer thermoelectric device and a method for making the same. Merely by way of example, embodiments of the invention provide a method to achieve substantial reduction of process complexity, number of steps, and cost of thermoelectric module assembly that would entail the transformation of a single substrate of material into an entire thermoelectric device.

In a specific embodiment, the present invention provides a uniwafer device for thermoelectric applications. The device includes one or more first thermoelectric elements comprising a first patterned portion of a substrate material. Each of the one or more first thermoelectric elements is configured to be functionalized as an n-type semiconductor with a thermoelectric figure of merit ZT of 0.2 and greater. Additionally, the device includes one or more second thermoelectric elements comprising a second patterned portion of the substrate material. The second patterned portion is separated from the first patterned portion by an intermediate region. Each of the one or more second thermoelectric elements is configured to be functionalized as a p-type semiconductor with a thermoelectric figure of merit ZT of 0.2 and greater. The one or more first thermoelectric elements and the one or more second thermoelectric elements are spatially configured to allow the formation of a first contact region and a second contact region respectively connecting to each of the one or more first thermoelectric elements and/or the one or more second thermoelectric elements, thereby forming a continuous electric circuit.

In an alternative embodiment, the present invention provides a method of making a uniwafer thermoelectric device. The method includes providing a substrate of material having a front surface region and a back surface region. The method further includes processing at least a portion of the substrate of material to have a thermoelectric figure of merit parameter ZT of 0.2 or greater. Additionally, the method includes patterning the portion of the substrate of material to form one or more first regions and one or more second regions separated by an intermediate region. Furthermore, the method includes processing the one or more first regions to yield n-type semiconductor characteristics and processing the one or more second regions to yield p-type semiconductor characteristics. Moreover, the method includes configuring the one or more first regions and the one or more second regions to allow formation of a first contact region and a second contact region to interconnect electrically to the one or more first regions and the one or more second regions such that a continuous electric circuit is formed within the portion of the substrate material. The first contact region and the second contact region are respectively associated with at least one of the front surface region and the back surface region.

In yet another alternative embodiment, the present invention provides a uniwafer device for thermoelectric applications. The device includes a plurality of thermoelectric elements comprising a portion of material within a single substrate having a front surface region and a back surface region. The portion of material is functionalized with a thermoelectric figure of merit ZT of at least 0.2. The plurality of thermoelectric elements is spatially arranged with one or more n-type semiconductor regions and one or more p-type semiconductor regions separated by an intermediate region serving partially as a thermal isolator and partially as an electric interconnect. Additionally, the uniwafer device includes a first patterned electrode overlying the front surface region to electrically interconnect with each of the plurality of thermoelectric elements in a first configuration. Furthermore, the device includes a second patterned electrode at least partially overlying the back surface region to electrically interconnect with each of the plurality of thermoelectric elements in a second configuration. The second configuration and the first configuration are combined to form a continuous electric circuit within the single substrate connecting the plurality of thermoelectric elements.

Depending on certain embodiments, one or more benefits can be achieved with the uniwafer thermoelectric device. Advantages of the present invention over conventional assembled thermoelectric device include permitting the uses of broad ranges of substrate materials for enhancing the thermoelectric figure of merit of the functionalized regions, and simplifying the processes for spatially arranging a plurality of thermoelectric elements and configuring both thermal and electric interconnects thereof. Additionally, advantages lie in the utilization of well established semiconductor wafer processing technologies and low cost manufacturing foundries to substantially reduce the cost of the thermoelectric devices. These and other benefits will be described in more detailed throughout the present specification and particularly below.

### BRIEF DESCRIPTION OF THE DRAWINGS

FIG. 1 is a cross-sectional schematic of a uniwafer thermoelectric device according to certain embodiments of the present invention.

FIG. 2 is a plane view schematic of a uniwafer thermoelectric device according to certain embodiments of the present invention, where black portions represent functionalized p-type semiconductor regions and white portions, n-type semiconductor regions.

FIGS. 3A-3F are plane view schematics of thermoelectric devices formed in a single wafer of material having one or more n-type thermoelectric elements and one or more p-type thermoelectric elements with stonehenge-like or ribbon-like structures arranged between front and back of the wafer material according to one or more embodiments of the present invention.

FIG. 4 is a flow chart illustrating a method for fabricating a uniwafer module for thermoelectric application according to an alternative embodiment of the present invention.

FIG. 5 is a flow chart illustrating a method for fabricating a uniwafer module for thermoelectric application according to an alternative embodiment of the present invention.

FIG. 6 is a flow chart illustrating a method for fabricating a uniwafer module for thermoelectric application according to an alternative embodiment of the present invention.

### DETAILED DESCRIPTION OF THE INVENTION

The present invention relates generally to thermoelectric devices. More particularly, the present invention provides a uniwafer thermoelectric device and a method for making the same. Merely by way of example, embodiments of the invention provide a method to achieve substantial reduction of process complexity, number of steps, and cost of thermoelectric module assembly that would entail the transformation of a single wafer of material into an entire thermoelectric device.

In accordance with certain embodiments of the present invention, one method to achieve reduction of the complexity, number of steps, and cost of thermoelectric module assembly would entail the transformation of a single wafer of material into an entire thermoelectric device. For example, one such wafer this could be accomplished in is one made from silicon. We herein outline an exemplary method by which to achieve this basic structure in accordance with certain embodiments of the present invention.

Firstly, a substrate of material is functionalized so as to achieve a reasonable thermoelectric performance. For example, this can be achieved by inducing nanostructures in the substrate via a subtractive method, e.g., not by growing additional material on the substrate but by removing material from the substrate itself such that one or more nano-scale morphologies remain with the substrate. According to one embodiment, these nanostructures can be zero-, one-, two-, or three dimensional in nature. In another embodiment, nano-structuring can induce an enhancement of the thermoelectric performance of a material. For example, this performance can be characterized by the “thermoelectric figure of merit” Z, given as Z=S²σ/k, where S is the Seebeck coefficient, σ is the electrical conductivity, and k is the thermal conductivity of the thermoelectric material. This is more commonly expressed as the dimensionless figure of merit ZT by multiplying it with the average temperature T for the subjected matters in application. In an example, functionalizing the selected region of material for enhancing the thermoelectric figure of merit ZT can be achieved by alloying or doping the subjected region to modify the electric band structure so that electric conductivity is enhanced while thermal conductivity is reduced. In another example, an improvement in ZT by orders of magnitude can be accomplished in a nano-structured material over the bulk specifically due to the enhancement of electric conductivity and reduction of phonon induced thermal conductivity.

Because a thermoelectric module or device often needs both n- and p-type semiconductor materials to achieve a series electrical circuit that effectively operates in a temperature gradient, a method to fabricate a thermoelectric module from a single piece of material should consider, for example, the doping of that material both n- and p-type. Therefore, a thermoelectric module can comprises a single substrate material that can be doped either n- or p-type in different regions or volumes of itself. This is often done via ion implantation or a solution-based or gas-phase dopants that is then annealed into a substrate such as silicon to make transistors and other functional devices. In the case where nanostructures comprise the functional thermoelectric volume within the wafer, these nanostructures may be doped with either n-type or p-type dopants according to certain embodiments of the present invention.

In one embodiment, a feature of the structure of the thermoelectric device is the ability to form electrical contact between pairs of n-type and p-type legs. For example, this can be achieved through patterning and etch techniques to form electrical contacts to pairs of adjacent thermoelectric legs that exist side-by-side on the top and bottom of the wafer. Contacts can be translated by one leg unit between the top and bottom of the wafer so as to maintain a series electrical connection, whereby the thermal gradient exists more or less perpendicular to the planar axes of the wafer. In certain embodiments of the present invention, the contact can be made either via doping silicon to high carrier concentrations, the deposition of one or more metals, and/or the formation of a silicide from these metals.

In certain embodiments of the present invention, a single wafer of material that has been pre-processed as a single- or poly-crystal comprising one or more elements such as silicon can be transformed into a thermoelectric module that has an electrically series, thermally parallel connection of n- and p-type semiconductor thermoelectric legs. For example, the wafer can be functionalized in a fashion that improves its thermoelectric figure of merit ZT, such as via inducing nano-scale features into the wafer material. These can be metalized such that the thermoelectric can be effectively used to pump heat with an applied current or generate electricity in an applied temperature gradient according to some embodiments of the present invention.

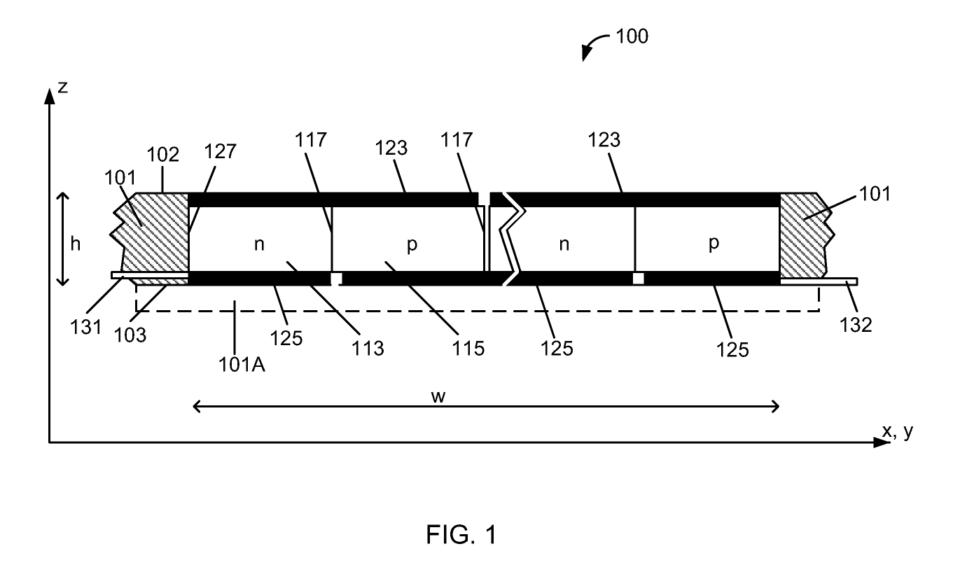

FIG. 1 is a cross-sectional schematic of a single-wafer thermoelectric device according to certain embodiments of the present invention. This schematic diagram is merely an example, which should not limit the scope of the claims herein. As shown, a single-wafer thermoelectric device 100 is made within a single wafer of material 101. A portion of the single wafer of material is processed to be divided into a plurality of first regions and a plurality of second regions respectively separated by an intermediate region. In an embodiment, the single wafer of material can be a crystal or alloy or composite material made from a group of elements consisting of Si, Ge, C, Mg, Al, Ni, Fe, W, Ti, Bi, Te, Pb, Ag, Au, Cs, Ca, O, Co, Cr, B, P, As, Sr, Na, and the like. For example, a Si wafer substrate is used, aiming for taking advantage of well established Si-based semiconductor processing techniques and low cost manufacturing foundry. Alternatively, wafer substrates made from an Si—Ge alloy, magnesium silicide, or iron silicide can also be preferred substrate materials.

In a specific embodiment, a patterning process can be performed using established semiconductor manufacturing techniques to define one or more first regions and one or more second regions within a portion of the wafer of material. The patterning techniques may include photomasking, e-beam or ion-beam illumination, lithography, deposition, etching, and more. In an example, the process is performed from a front side 102 of the wafer substrate 101. Each defined first or second region can have one or more structures retaining a volume of wafer material in a dimension ranging from nanometers to centimeters in cubic volume. In addition, the defined first or second region can be respectively treated or functionalized to enhance its thermoelectric properties. In particular, the first or second region can be annealed, chemically treated, implanted, or doped to alter its electronic band structure for enhancing electric conductivity while reducing thermal conductivity, leading to an enhancement of the thermoelectric figure of merit. For example, the desired figure of merit ZT of the corresponding first or second region can be improved to 0.2 or greater. Furthermore, by implanting corresponding dopants or by either thermo-chemical diffusion or ion-implantation, the first or second region can be additionally functionalized as an n-type semiconductor and a p-type semiconductor, respectively serving as n-type and p-type thermoelectric elements to provide carrier charges. In one or more preferred embodiments, for several kinds of substrates made by semiconductor or semimetal materials, n-type dopants selected from phosphorous, arsenic, antimony are used and p-type dopants selected from boron, aluminum, indium, and gallium are often used.

As a result of one or more functionalizing processes mentioned above, the single-wafer device 100 includes one or more n-type regions 113 and one or more p-type region 115 separated by an intermediate region 117. The intermediate region 117 is characterized as a boundary region between the two neighboring functional n- and p-regions. In an embodiment, the intermediate region 117 can be a space ranging from infinitesimal to any measurable dimension within the portion of the single wafer of material 101. In a specific embodiment, the intermediate region 117 can also bear the wafer material but be re-configured or functionalized to be a substantial electric insulator and a good thermal isolator with thermal conductivity of about 10 W/m·K or less. In another specific embodiment, the intermediate region 117 can be functionalized to be an electric interconnect used for coupling the n- or p-type semiconductor with a metal-based contact region. In another embodiment, the intermediate region 127 also exists at the boundary of the functionalized region of the device 100 and any non-functionalized portion of the substrate 101. Of course, there can be other variations, alternatives, and modifications to the nano-structuring, doping, and interfacing treatments associated with the functionalized n- and p-type regions within the single wafer of material. For example, each of the n- and p-type functionalized regions 113, 115 is formed with an average depth h from the front side 102 into the wafer substrate 101. The average depth h can be up to ½, ⅔, ⅗, ¾, 9/10 and greater of a portion of the total wafer thickness. In an example, h is about 100 nm and greater.

Referring to FIG. 1, the single-wafer device 100 further includes one or more conductor shunts 123 formed overlying the functionalized n-type regions 113 and p-type regions 115 from the front side 102 of the wafer substrate 101. Additionally, the wafer substrate 101 can be processed to remove a partial portion of the wafer material 101A from a back side 103 of the substrate 101. At least the removal of the partial portion of wafer material 101A can be up to ½, ⅓, ⅖, ¼, 1/10 or less of a portion of the wafer thickness of the substrate 101 to expose the functionalized n-type regions 113 and p-type regions 115 from the back side 103. As a result, the single-wafer device 100 further includes one or more conductor shunts 125 formed overlying the exposed n-type regions 113 and p-type regions 115 from the back side 103. Both the conductor shunts 123 and 125 can be added and patterned using established semiconductor processing techniques to form electric contact regions over different surface regions based on a predetermined configuration and arrangement of the functionalized regions. For example, patterning using various masks, metal depositing, ion-etching, and more techniques are used. As an example shown in FIG. 1, the electric coupling formed between the conductor shunts 123, 125 and the functional regions 113, 115 are substantially in a two dimensional configuration respectively overlying partially the front side 102 and back side 103 of the wafer substrate 101. Although not shown in FIG. 1, the electric contact regions can also be formed in a two-dimensional pattern for matching the surface arrangement of all the functionalized regions. Further, the electric contact regions can include structures formed into a certain depth of the wafer substrate 101 depending on the detail spatial structures of the functionalized n- and p-type regions 113, 115 and corresponding intermediate regions 117. In a specific embodiment, the electric coupling between the conductor shunts 123 with the n-type regions 113 and p-type regions 115 at the front side 102 forms a first interconnect configuration for bridging an n-p pair of regions, or a group of n regions and a group of p regions, or other combinations. Correspondingly, the electric coupling between the conductor shunts 125 with the exposed n-type regions 113 and p-type regions 115 at the back side 103 forms a second interconnect configuration. The first interconnect configuration and the second interconnect configuration combines to lead to a formation of a complete electric circuit between all the functionalized regions. The electric circuit can be such that n-p pairs of legs are either electrically in series, in parallel, or in a combination of serial and parallel connections. The single-wafer device 100 can have two external leads 131 and 132 made by metal and respectively coupled to two terminals of the electric circuit. As an implementation of the present invention, the two external electric leads 131 and 132 can used as two electrodes for outputting electric power induced by thermoelectric effect when the single-wafer device 100 is subjecting the conductor shunts 123 at the front side 102 and conductors 125 at the back side 103 to a temperature gradient. According to one or more embodiments, the conductor shunts 123 and 125 can be respectively configured to form good thermal contacts with corresponding external objects in application. In another embodiment, the single wafer device 100 can also be used to transfer thermal energy from the front side 102 to the back side 103 when an external voltage from a power source is supplied the two external leads 131 and 132.

In a specific embodiment, the single-wafer device 100 is substantially in a planar shape, aiming to have bigger surface areas for both the front side and back side to make thermal contacts with subject matters in thermoelectric applications. For example, as shown in FIG. 1, the device 100 may have a nominal dimension h along a z direction perpendicular to the surface of wafer substrate 101, determined primarily by the functionalized n-type and p-type regions and secondarily depended on the configuration of the conductor shunts. Along any x, y direction in the plane of wafer substrate 101, the device 100 can have a lateral dimension w determined by the size of the total functional portion of the wafer substrate 101. In an embodiment, the nominal dimension h is an average depth partially into a thickness of the wafer substrate 101 from the front side 102 substantially less than one-fifth of the lateral dimension w. In an example, h can be as small as a few hundred nanometers and w can be as large as any wafer substrate size.

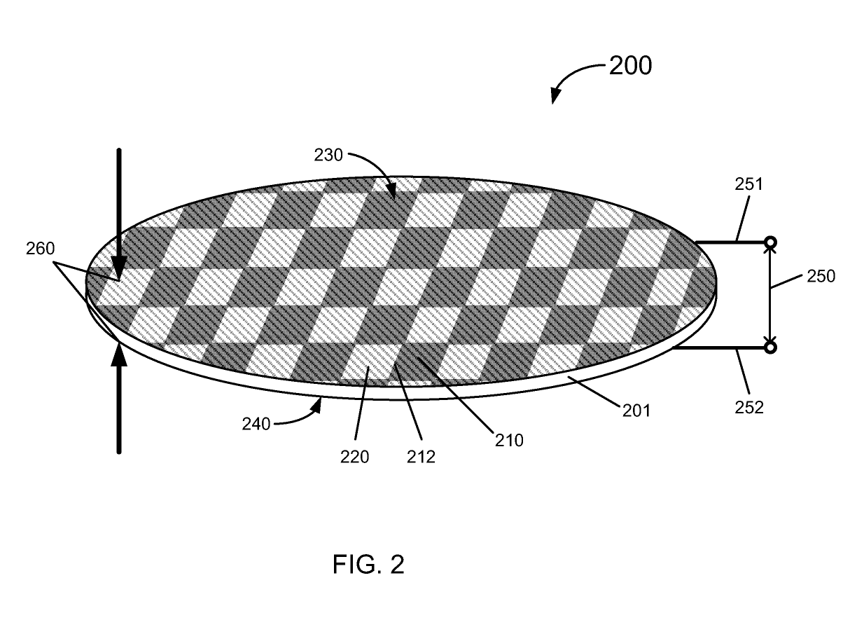

FIG. 2 is a plane view schematic of a uniwafer thermoelectric device according to some embodiments of the present invention, where black patches represent thermoelectrically functionalized p-type semiconductor regions and white ones, thermoelectrically functionalized n-type semiconductor regions. This schematic diagram is merely an example, which should not limit the scope of the claims herein. As shown, the whole wafer 201 can be processed according to one or more embodiments of the present invention to be a thermoelectric device 200. In a specific embodiment, the wafer 201 is patterned and treated from either a front surface 230 or a back surface 240 to form a plurality of first functionalized regions 210 respectively separated from a plurality of second functionalized regions 220. The combined first functionalized regions 210 and second functionalized regions 220 covers substantially the whole surface area except an intermediate boundary region 212. In certain embodiments, the boundary regions 212 can be any finite dimension and even reduced to infinitesimal in size to allow the first region 210 substantially next to the second functionalized region 220. Each of the plurality of first functionalized regions 210 comprises a portion of substrate material processed to bear p-type semiconductor characteristics and each of the plurality of second functionalized regions 220 comprises a portion of substrate material processed to bear n-type semiconductor characteristics. Both functionalized regions are characterized by an enhanced thermoelectric figure of merit ZT of greater than 0.2.

Additionally in an example, the functionalizing process of the n- and p-type regions can be performed down to a depth from the front surface 230 partially into the thickness of the wafer 201. The front surface 230 of the wafer 201 with all the functionalized n- and p-type regions can be coupled with a patterned top conductive shunt. The back surface 240 of the wafer 201, not visible in the plane view, can be processed to remove extra portions of the wafer material to expose at least partially the functionalized n- and p-type regions (210 and 220). Subsequently, a patterned bottom conductive shunt can be placed to couple with the exposed n- and p-type regions from the back surface 240. In an embodiment, each of the top conductive shunt and the bottom conductive shunt can be built into the wafer of material by transforming the intrinsic wafer material into a conductor by various chemical or thermal treatments. In another embodiment, both conductive shunts are formed by adding an external material onto the wafer substrate. In yet another embodiment, both the conductive shunts are formed on two external objects that are custom matched respectively with the corresponding arrangement of the functionalized n- and p-type regions on the front side and back side. Overall, the whole-wafer device 200, either stand-alone or in a designated position of applying to the external objects, includes a complete electric circuit connecting all the functionalized regions. The electric circuit can be formed with a combination of series and parallel connections through the conductive shunt on the front surface to the conductive shunt on the back surface to interconnect each of the n-type regions and each of the p-type regions. As shown in FIG. 2, the electric circuit has two external electrodes 251 and 252, respectively coupled to either a terminal of the front conductive shunt or a terminal of the back conductive shunt depending on the specific electronic configuration.

In a specific embodiment, the whole wafer thermoelectric device 200 can be used to generate an electric bias 250 between the two external electrodes 251 and 252 when the device is subjected to a temperature gradient across the front surface 230 and back surface 240. The front conductive shunt is configured to form a thermal contact with a subjected hot source, such as, for example a car's exhaust pipe or a furnace body, and the back conductive shunt is configured to form a thermal contact with a cooling apparatus (for example a running fluid coolant), so that the maintained temperature gradient between the front shunt and back shunt can induce a steady electric current outputted via the two leads 251 and 252 for various powered applications. In another example, the front side may be in thermal contact with a heat source with a high-to-low temperature profile across the wafer surface, depending on a specific heat dissipation scheme, and the back side may be in thermal contact with a cooling source (heat sink) with a low-to-high temperature profile across the opposite side of the wafer surface depending on a specific cooler design. Across a spatial distance of the wafer, there is a distribution of temperature gradients across the same distance. In particular, when the two fluxes are arranged in opposite directions, a uniwafer device 200 with a plurality of functionalized thermoelectric elements can be laterally aligned with specifically patterned and proper lateral dimensions of each n- and p-region to accommodate the variation of temperature gradients across the distance for achieving maximized thermoelectric performance efficiency. In another specific embodiment, the uniwafer thermoelectric device 200 can be used for pumping thermal energy out of a subjected surface through all the functionalized n- and p-type regions coupled between the front shunts and the back shunts when an external control voltage is applied to the two leads 251 and 252.

In certain embodiments of the present invention, the thermoelectric module comprises a substrate material that may further comprise of a metal, insulator, semiconductor or semimetal. For instance, the substrate material can be made up of one or a combination of Si, Ge, C, Mg, Al, Ni, Fe, W, Ti, Bi, Te, Pb, Ag, Au, Cs, Ca, O, Co, Cr, B, P, As, Sr, Na, or the like. According to certain embodiments of the present invention, these substrate materials may have an aspect ratio such that its thickness in one axis (normal to the surface of the substrate) is less than one-fifth of that in both other axes within the plane of the substrate, although this is not required or limited by the embodiments, for enhancing relative contact areas subjecting to the temperature gradient. Also, 0-D, 1-D, 2-D, or 3-D nano-structuring can be induced within the single wafer of material to functionalize each of them to be either an n- or a p-type thermoelectric element with an enhanced figure of merit ZT. Each of the corresponding nano-structures can be generated in the substrate itself via one or more subtractive and/or printing techniques, which may be performed through at least a solution, plasma, ion etching, or roll-to-roll technique. In a specific embodiment, the nano-structures, depending on its n- or p-type semiconductor characteristics, can be grouped by coupling with conductive shunts in a certain configuration to form one or more nano-structured volumes. Each of the nano-structured volumes acts as a thermoelectric element that generates a bias in an applied temperature gradient or pumps heat in an applied electric field.

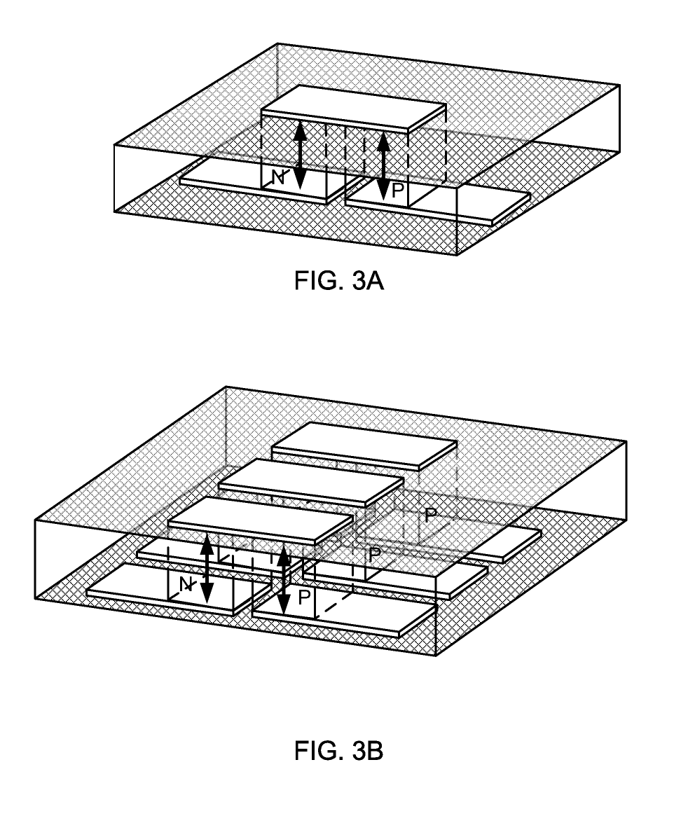

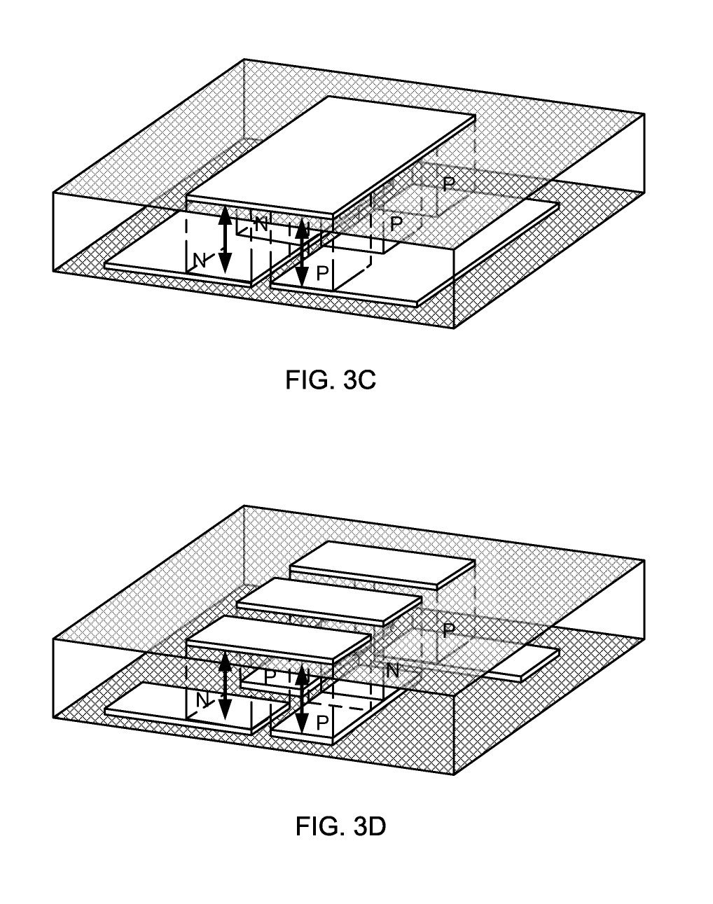

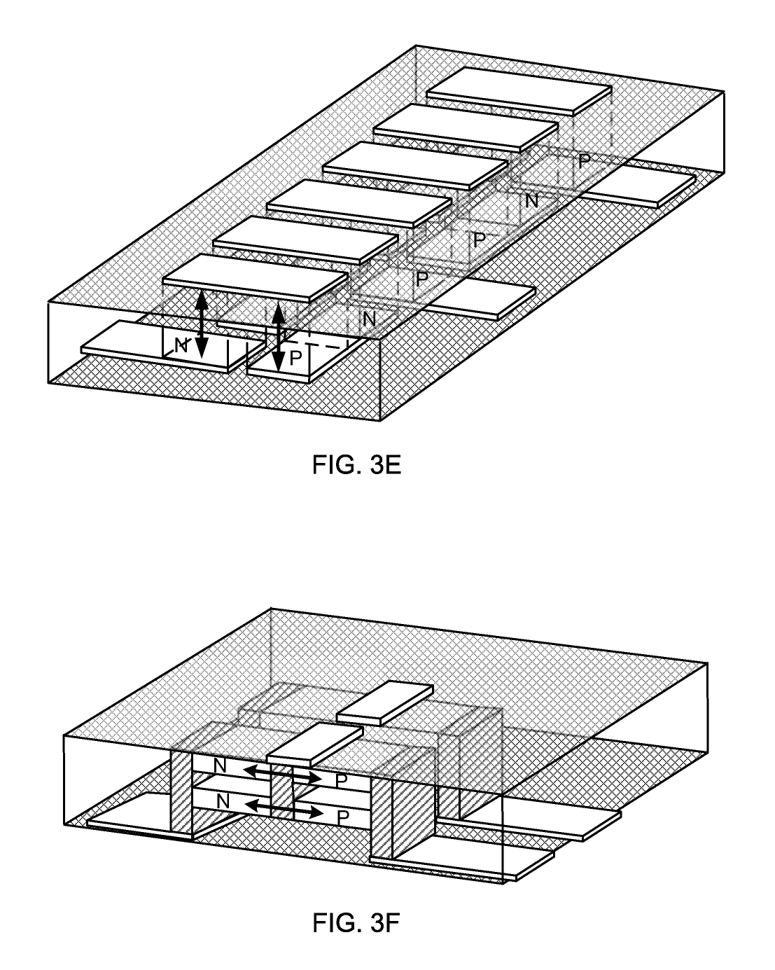

FIGS. 3A-3F show exemplary functionalized thermoelectric volumes formed within a single wafer of material and coupled electrically in various configurations according to embodiments of the present invention. In some embodiments of the present invention, each of the functionalized thermoelectric volumes can be simplified as a shaped leg within a portion of a single wafer connected between two conductor shunts, each of which can be thermally and electrically associated with either the front side or the back side of the single wafer of material. As shown in FIG. 3A, a simple thermoelectric volume includes a pair of legs functionalized respectively to bear n-type or p-type characteristics. In an embodiment, the n-type thermoelectric leg comprises a nanostructure made of quantum dots of material doped with n-type dopants. In an example, the nanostructure as shown is in a simple quantum dot composite formed vertically within the wafer. Similarly, next to the n-type leg the p-type thermoelectric leg comprises a portion of wafer material doped with p-type dopants and also is configured to be a quantum dot composite structure. In an example, the thermoelectric volume is connected to a conductive shunt electrically from the front side which may be made by a different material other than the wafer material. For example, the second material is made from copper so as to be a well conducting material both thermally and electrically, and the n-type leg and p-type leg are connected electrically by two patterned conductive shunts from the back side to form an electric path alternatively through n- and p-type semiconductor regions. In another embodiment, the thermoelectric volume is contacted electrically a second time by a third conductive material different from the substrate material or by the substrate itself. For example, the thermoelectric volume is coupled with one or more patterned conductive shunts to form electric contacts associated with the third material. The third material may be selected for forming an ohmic contacts, barrier contacts, local interconnects, and diffusion barriers. For example, for a thermoelectric device based on a single silicon wafer a silicide material is interfaced between the conductive shunts and semiconductor legs. Additionally, an intermediate region made by the substrate itself but reconfigured to become a substantially good thermal insulator and electric insulator. For example, the intermediate region that separates the functional legs may have its thermal conductivity less than 10 W/m·K.

In certain embodiments of the present invention, the thermoelectric device may comprise one or more of the n- and p-type thermoelectric volumes. In some embodiments of the present invention, a geometry whereby one or more thermoelectric volumes having nano-structures that are doped n-type and one or more thermoelectric volumes having nanostructures that are doped p-type are spatially arranged side-by-side within the substrate material. FIG. 3B shows an example of these thermoelectric volumes formed side-by-side and respectively coupled to a piece of conductive shunt so that all the electric paths through these thermoelectric volumes are electrically in parallel, provided that a temperature gradient exists from the top shunt to bottom shunt. FIG. 3C shows another example whereby the one or more thermoelectric volumes are grouped respectively for n-type legs and p-type legs. The thermoelectric volumes are coupled electrically in parallel with a common conductor shunt on the top side and respectively with two common conductor shunts on the bottom side. In an alternative embodiment, each n-type group is a thermoelectric volume comprising one or more nano-structured legs formed by a portion of wafer material doped with n-type dopants and each p-type group is a thermoelectric volume comprising one or more nano-structured legs formed by a portion of wafer material doped with p-type dopants.

In some embodiments of the present invention, the thermally induced current flows through n-type legs of the thermoelectric volumes having nanostructures that are doped n-type and through p-type legs of the thermoelectric volumes having nanostructures that are doped p-type, alternately. FIG. 3D shows an example that multiple functionalized n-type and p-type regions are formed alternatively side-by-side and each pair of n-type and p-type regions is respectively coupled with a top shunt and a bottom shunt alternatively. This leads to a formation of a thermoelectric circuit connected electrically in series. In an alternative embodiment, FIG. 3E shows that multiple functionalized n-type and p-type regions couple with top and bottom conductor shunts to form a thermoelectric path in a combination of electrically serial and parallel connections. In some embodiments of the present invention, the substrate wafer is at least partially configured in such a way that thermoelectric volumes with n-type doped nanostructures, thermoelectric volumes with p-type doped nanostructures, and thermoelectric volumes with both doped n-type and doped p-type nanostructures all exist within the same general direction of heat flow from the top surface to bottom surface of the substrate wafer.

In an alternative embodiment, the functionalized thermoelectric volumes within the single wafer of material are characterized as nanoribbon-like structures primarily aligned in parallel to the wafer substrate. FIG. 3F shows an example that multiple functionalized thermoelectric volumes each with a nano-ribbon structure are arranged substantially in parallel with the substrate and one n-type doped structure is side with one p-type doped structure. Along the substrate plane direction a pair of n-type and p-type doped ribbon structures are coupled by an interconnect material disposed at the intermediate region. Along the vertical direction, there can be one or more redundant pairs of n-type and p-type ribbon structures stacked together (separated by the intermediate region). The interconnect material is configured to couple each of them one by one. In an embodiment, using the interconnect material an electric path for the uniwafer thermoelectric device is formed within the wafer substrate to respectively connect the n-type structures or p-type structures electrically in parallel and also connect all the n-type structures with all the p-type structures electrically in series. In a specific embodiment, the interconnect material is transformed from the substrate material to bear both substantially electric conducting and good thermal conducting characteristics. In addition, a top patterned shunt forms a thermal contact with a portion of the interconnect material from the top side of the wafer substrate and a bottom patterned shunt forms another thermal contact with alternate portion of the interconnect material from the bottom side. The top shunt and bottom shunt are configured to respectively form thermal contacts with external objects having temperature gradients such that a thermal path for the uniwafer thermoelectric device is formed. Of course, there can be many variations, alternatives, and modifications.

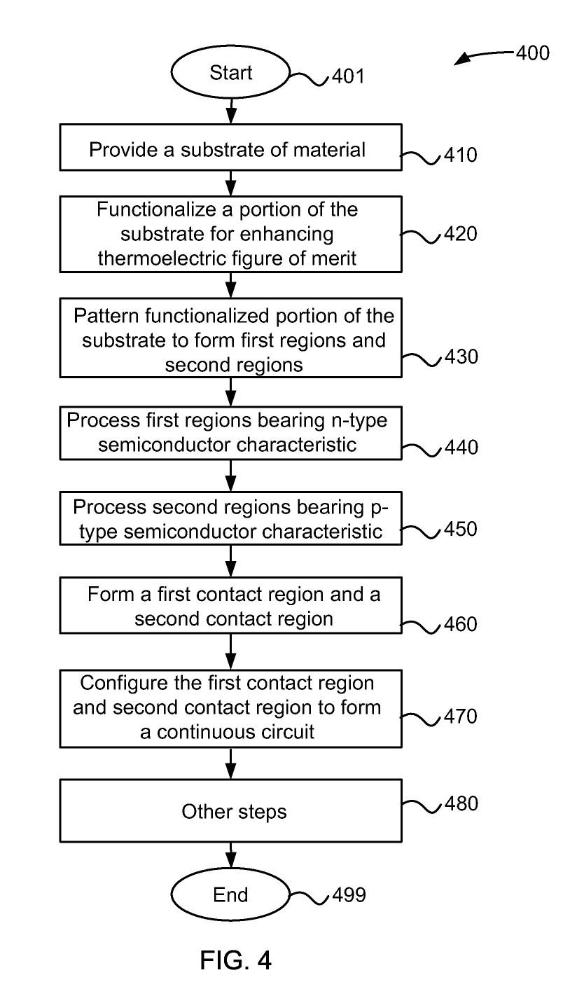

According to a specific embodiment, the present invention also provides a method of making a uniwafer device for generating electric current from a temperature gradient. FIG. 4 is a flow chart illustrating a method for making a uniwafer device for thermoelectric application according to an alternative embodiment of the present invention. This diagram is merely an example, which should not unduly limit the scope of the claims herein. One of ordinary skill in the art would recognize other variations, modifications, and alternatives. It is also understood that the examples and embodiments described herein are for illustrative purposes only and that various modifications or changes in light thereof will be suggested to persons skilled in the art and are to be included within the spirit and purview of this process and scope of the appended claims.

As shown in FIG. 4, the present method can be briefly outlined below.
1. Start;
2. Provide a substrate of material;
3. Functionalize a portion of the substrate to enhance thermoelectric figure of merit ZT of at least 0.2;
4. Pattern the functionalized portion to form one or more first regions and one or more second regions;
5. Process the one or more first regions to yield n-type semiconductor characteristics;
6. Process the one or more second regions to yield p-type semiconductor characteristics;
7. Form a first contact region and a second contact region;
8. Configure the first contact region and the second contact region respectively to couple each of the first and second regions to form a continuous circuit;
9. Perform other steps;
10. End.

These steps are merely examples and should not unduly limit the scope of the claims herein. As shown, the above method provides an improved technique of fabricating a thermoelectric device from a single substrate of material. In a preferred embodiment, the method uses a substrate that is made of at least a substrate material including a metal, insulator, semiconductor and/or semimetal. Depending on the substrate material, at least a portion of the substrate can be correspondingly processed to form one or more thermoelectric functionalized volumes. Further steps can then be performed to make a uniwafer thermoelectric device. One of ordinary skill in the art would recognize many other variations, modifications, and alternatives. Various steps outlined above may be added, removed, modified, rearranged, repeated, switched in order, and/or overlapped, as contemplated within the scope of the invention.

As shown in FIG. 4, the method 400 starts with a start step 401. According to certain embodiments, the present invention provides a method for making a thermoelectric module based on a single substrate made of at least a first substrate material, and the first substrate material includes a metal, insulator, semiconductor and/or semimetal. For example, the first substrate material includes one or a combination of some selected from material elements Si, Ge, C, Mg, Al, Ni, Fe, W, Ti, Bi, Te, Pb, Ag, Au, Cs, Ca, O, Co, Cr, B, P, As, Sr, and Na. The method 400 follows with a step 410 by providing such a substrate of material. In an example, the substrate is a wafer having an aspect ratio such that its thickness in its normal axis is less than one-fifth of dimensions in both other axes. In yet another example, the method includes providing a substrate of material that has been available in the semiconductor industry with well established wafer treatment techniques. For example, the substrate is a standard silicon wafer made by substantially pure single-crystal or poly-crystal silicon. Alternatively, wafer substrate made by silicon-germanium alloy, magnesium silicide, iron silicide, and more can be used. As a result, many wafer handling and pre-treatment processes established in Si-based semiconductor industry can be utilized, which provides a huge advantage for making the claimed device with a substantially low cost. Of course, there can be other variations, modifications, and alternatives.

After the substrate is ready subsequent to a preparation step, a step 420 of functionalizing a portion of the substrate for forming the uniwafer thermoelectric device can be performed. The functionalizing process is substantially to alter the substrate material microscopically to enhance its thermoelectric properties. This includes selecting a material with an electronic band gap, altering its electronic band structure to enhance both its Seebeck coefficient and electrical conductivity by doping or alloying, altering its phonon scattering characteristics by changing its crystal structure through nanostructuring, doping, etching etc. to reduce thermal conductivity, and more. Ultimately, the functionalizing process aims to at least improve the thermoelectric figure of merit ZT to greater than 0.2.

In a specific embodiment, the functionalized region can be a thermoelectric element comprising a volume of functionalized substrate material with nanometer dimensions. On the one hand, nanostructuring has been utilized as an effective way of enhancing the thermoelectric figure of merit for specific regions of the substrate material. On the other hand, nanostructuring also becomes a process for defining each thermoelectric element for making the uniwafer thermoelectric device. For example, in step 430 of the method 400 the functionalized portion of material can be patterned to form one or more nano-scaled structures in various morphologies including zero-dimensional features (such as quantum dots), or one-dimensional nanowires, or two-dimensional ribbons, or three-dimensional network structures, or a combination of those lower-dimensional structures. Depending on the particular material of the substrate, the patterning process can be performed using various well-established techniques including masking, chemical or ion etching, particle beam illumination or lithography, annealing or printing, to define a spatial range for each of the one or more regions. In an example, the functional portion of the substrate material is patterned to form one or more first regions spatially separated with one or more second regions by an intermediate region within the substrate. The intermediate region by itself either can retain substantially the substrate material with certain modifications including doping, alloying, or restructuring, or be subtracted then filled with extrinsic materials for different purposes. In an embodiment, the intermediate region can have a spatial dimension ranging from infinitesimal to any measurable dimension within the first portion. Of course, there can be many variations, alternatives, and modifications.

Once the spatial regions are defined, the method 400 further includes a step 440 for processing each of the one or more first regions bearing an n-type semiconductor characteristic and a step 450 for processing each of the one or more second regions bearing an p-type semiconductor characteristic. In a specific embodiment, either the step 440 and 450 is further to make a functional region into a true thermoelectric element providing a charge carrier and a thermal path for the claimed uniwafer thermoelectric device. In another specific embodiment, both steps include introducing one or more impurity elements into each of the specific nano-structured regions just defined above in step 430. In particular, for making a thermoelectric device, the step 440 includes forming one or more n-type doped nano-structures respectively within one or more first regions and the step 450 includes forming one or more p-type doped nano-structures respectively within one or more second regions. The one or more n-type doped nano-structures and the one or more p-type doped nano-structures can be grouped in certain configuration to form one or more thermoelectric volumes to substantially utilize the functionalized portion of the substrate material. The spatial configuration of the thermoelectric volume is also determined by how the thermal flux or temperature gradient the device would be handled. In an embodiment, all the formed thermoelectric volumes are located substantially within a same general direction of a heat flow that is supposed to pass through the substrate from a front side to a back side. In another embodiment, all the thermoelectric volumes are formed substantially with an average depth partially into the thickness of the substrate from a front side. In yet another embodiment, at least a portion of the intermediate region that separates the side-by-side disposed n- and p-type regions can be processed to be substantially electrically insulating and also a thermal isolator with a desired thermal conductivity less than 10 W/m K. In an alternative embodiment, part of the intermediate region is processed to become an electric interconnect between the nearest n- and p-type regions and serves as a good thermal conductor with a patterned contact region. In an example, the substrate material is retained within intermediate region. In another example, the substrate material is removed or subtracted from the intermediate region and a new material can be introduced to fill in.

In a specific embodiment, the 0-D, 1-D, 2-D, or 3-D nano-structuring process mentioned above is induced based on a single substrate of material. For example, one or more corresponding nano-structures are generated in the substrate via one or more subtractive techniques. In particular, one or more subtractive techniques are performed through at least a solution etching, plasma etching, or ion etching technique. In an example, the substrate material includes one or a combination of some material elements selected from Si, Ge, C, Mg, Al, Ni, Fe, W, Ti, Bi, Te, Pb, Ag, Au, Cs, Ca, O, Co, Cr, B, P, As, Sr, or Na. Preferably, Si, SiGe, magnesium silicide, iron silicide and more are often used to provide the wafer substrate. Correspondingly, one or more n-type dopants and one or more p-type dopants can be determined for functionalizing the one or more nano-structures. Typical n-type dopants for silicon include phosphorous, arsenic, antimony and p-type dopants include boron, aluminum, indium, and gallium. Of course, there are many variations, alternatives, and modifications that can be recognized by skilled in the art. The examples named above should not unduly limit the scope of the claims herein.

Referring to FIG. 4, the method 400 further includes a step 460 of forming a first contact region and a second contact region for the one or more n-type and p-type functionalized regions for making the uniwafer thermoelectric device. In a specific embodiment, a first patterned conductor is formed overlying the one or more first regions and one or more second regions on the front side of the wafer substrates and a second patterned conductor is formed underlying the one or more first regions and one or more second regions on the back side. The first and second patterned conductor firstly serves as electrical connectors for forming a continuous electric path and secondly serves as a thermal contact region which is configured to serve as a gate of a thermal path for the uniwafer thermoelectric device. In certain embodiments, the electric interconnect is formed via the functionalized intermediate region. The first and second patterned conductor primarily is configured to be a thermal contact region for the device. Both the first and second patterned conductor should be at a least good thermal conductor and shaped for making good thermal contact with a designated external object.

Subsequently, the method 400 includes a step 470 for configuring the first contact region and the second contact region to form a continuous electric circuit by connecting each of the n- and p-type functionalized thermoelectric regions in a certain configuration and at the same time to configure the first and second contact regions respectively to form thermal contacts with external objects having temperature gradient. In an example, a conductive material as an electric shunt is patterned to couple electrically from either side of the wafer substrate with each of the functionalized n-type and p-type regions in a specific configuration so that a continuous electric circuit is formed. This step may utilize many well established semiconductor processing techniques such as patterning, plating, coating, sputtering, and more to form electric contacts with each of the functionalized n-type and p-type regions in a predetermined spatial configuration. In particular, the shunt configuration may result in a plurality of electric connections in series, in parallel, or a specific combination of series and parallel connections. In an embodiment, the electric contacts between the first shunt can be assisted by adding a second material at the interface to enhance thermal and electrical conductivity. In yet another embodiment, the shunt coupling with the one or more functionalized n-type and p-type regions is determined for various thermoelectric applications that generate a bias in an applied temperature gradient or pump heat in an applied electric field.

Optionally, as shown in FIG. 3F, the electric contacts between n- and p-type functionalized regions are achieved by processing the intermediate region and transforming it into one or more interconnects. The step 470 also includes using patterning, doping, etching, or similar techniques for forming these interconnects themselves within the wafer substrate, then forming thermal contacts with the first patterned conductor or second patterned conductor in one or more configurations from either front side or back side of the wafer substrate. In an embodiment, the first and second patterned conductor comprises part of the wafer substrate wherein the substrate material is re-configured to become good thermal conductor. Alternatively, the method 400 includes an optional step for removing partially the substrate material from one side of the wafer so that one of the patterned conductor can be introduced to form the thermal link with the exposed thermoelectric volumes including all the nano-structures in n-type and p-type doped regions. This can be carried with one or more material subtraction techniques including physical, chemical, or even mechanical ways. The subtraction process can be done on the nano-scale to specifically remove substrate material in a vicinity of the previously functionalized n-type and p-type regions. In addition, the introduced conductor may be a different material from the substrate material, which can be determined by specific thermoelectric applications where not only good electric contact is desired but also good thermal contact with a specific subjected material is preferred.

Moreover, the method 400 can include other steps 480 to complete the fabrication process for the uniwafer thermoelectric devices in the end step 499. For example, other steps include forming a pair of external electric leads. Each of the two leads can be coupled respectively to two electric terminals associated with the continuous electric circuit formed in earlier steps. Some additional steps may include configuring the front side and back side respectively to form optimized thermal contacts with corresponding subject regions in specific thermoelectric applications. In yet another example, the one or more nano-structured thermoelectric volumes are contacted electrically by at least a second material. In yet another example, the one or more nano-structured thermoelectric volumes are further contacted electrically by a third material or by the first substrate material.

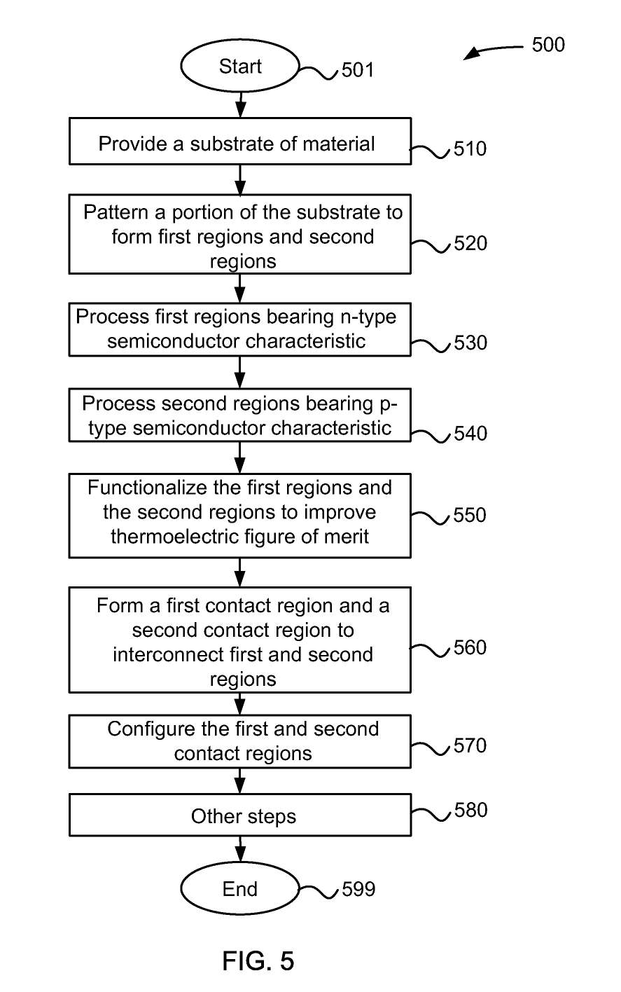

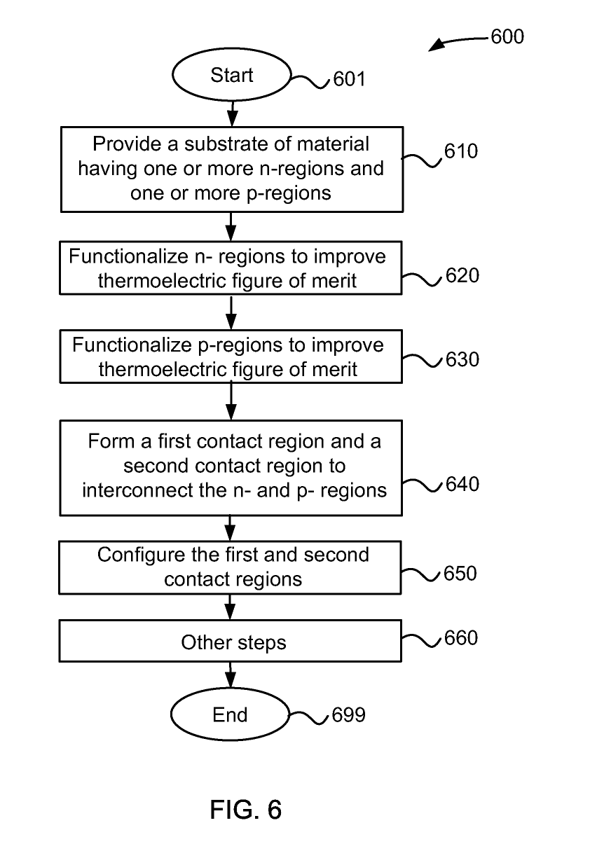

FIGS. 5 and 6 are schematic flow charts showing alternative methods for making a uniwafer thermoelectric module according to one or more embodiments of the present invention. These diagrams are merely examples, which should not limit the scope of the claims herein. As shown in FIG. 5, the method 500 includes step 501 for starting and step 510 for providing a substrate of material selected from one or a combination of Si, Ge, C, Mg, Al, Ni, Fe, W, Ti, Bi, Te, Pb, Ag, Au, Cs, Ca, O, Co, Cr, B, P, As, Sr, or Na. Step 520 includes patterning a portion of the substrate material into one or more first regions and one or more second regions separated by an intermediate region. The intermediate region can be infinitesimal or as large as any measurable dimension within the substrate of material. The patterned one or more first regions or one or more second regions can include a plurality of nanostructures formed in various morphologies, in 0D, 1D, 2D, or 3D characteristics. Step 530 includes processing the one or more first regions bearing an n-type semiconductor characteristics and Step 540 includes processing the one or more second regions bearing a p-type semiconductor characteristics. These steps may use doping, diffusion, solution-based alloying, ion-implantation, or the like to introduce proper impurity elements into the specific regions comprising the substrate material. Additionally, the method 500 includes a step 550 to functionalize the one or more n-type regions and one or more p-type regions and transform the band or material structures thereof to enhance specifically the thermoelectric figure of merit ZT at least above 0.2. Following that, the method also includes step 560 for forming a first contact region and a second contact region to interconnect each of the one or more n-type functionalized regions and each of the one or more p-type functionalized regions. The first contact region and the second contact region can be either for electric contact or for thermal contact or both. The method then includes step 570 for configuring the first contact region and the second contact region to form a continuous electric circuit connecting each of the n-type and p-type functionalized regions to turn each of them into a thermoelectric element of the uniwafer thermoelectric module. Other steps 580 may include forming electrical outlets and configuring the thermal contact regions with specific objects to be applied by the module. Of course, there can be other variations, alternatives, and modifications.

As shown in FIG. 6, the method 600 includes a starting step 601 and step 610 for providing a substrate of material that has been preprocessed to bear one or more n-type doped regions and one or more p-type doped regions. The substrate material may be selected from one or a combination of Si, Ge, C, Mg, Al, Ni, Fe, W, Ti, Bi, Te, Pb, Ag, Au, Cs, Ca, O, Co, Cr, B, P, As, Sr, or Na. In one or more preferred embodiments, the substrate material uses Si, or SiGe alloy, or compound magnesium silicide or iron silicide. N dopants would be phosphorous, arsenic, antimony and P dopants would be boron, aluminum, indium, and gallium, depending on embodiments. Step 620 includes functionalizing the one or more n-type regions and transforming the band or material structures thereof to enhance specifically the thermoelectric figure of merit ZT of at least 0.2. Step 630 includes functionalizing the one or more p-type regions and transforming the band or material structures thereof to enhance specifically the thermoelectric figure of merit ZT of at least 0.2. The functionalizing process may also include nanostructuring the one or more n-type regions or one or more p-type regions to form a plurality of nanostructures in various morphologies, in 0D, 1D, 2D, or 3D characteristics. Step 630 further includes using doping, diffusion, solution-based alloying, ion-implantation or the like to alter the electronic band structure or electron-phonon scattering scheme within each nanostructured region. Additionally, the method 600 includes a step 640 for forming a first contact region and a second contact region to interconnect each of the one or more n-type functionalized regions and each of the one or more p-type functionalized regions. The first contact region and the second contact region can be either for electric contact or for thermal contact or both. The method then includes step 650 for configuring the first contact region and the second contact region to form a continuous electric circuit connecting each of the n-type and p-type functionalized regions to turn each of them into a thermoelectric element of the uniwafer thermoelectric module. Other steps 660 may include forming electrical outlets and configuring the thermal contact regions with specific objects to be applied by the module. Of course, there can be other variations, alternatives, and modifications.

The above sequence of processes or steps provides a method for making a single-wafer device for thermoelectric applications according to one or more embodiments of the present invention. As shown, the method uses a combination of steps including providing a substrate of material as the basis for building functionalized regions of the claimed device therein. Further, the method uses a combination of steps for making one or more nano-structured thermoelectric volumes at least partially located substantially within the same general direction of a heat flow to be subjected by the claimed device. Other alternatives can also be provided where steps are added, one or more steps are removed, or one or more steps are provided in a different sequence without departing from the scope of the claims herein. Further details of the present method can be found throughout the present specification and below. In another embodiment, 0-D, 1-D, 2-D, or 3-D nano-structuring is induced, and one or more corresponding nano-structures with one or more nano-structured volumes are generated in the substrate via one or more printing techniques. In yet another example, the one or more printing techniques are performed through at least an imprint, deposition, or roll-to-roll technique. In yet another example, the first substrate material includes one or a combination of Si, Ge, C, Mg, Al, Ni, Fe, W, Ti, Bi, Te, Pb, Ag, Au, Cs, Ca, O, Co, Cr, B, P, As, Sr, or Na, the substrate has an aspect ratio such that its thickness in one axis is less than one-fifth of that in both other axes, and the one or more nano-structured volumes act as a thermoelectric volume that generates a bias in an applied temperature gradient or pumps heat in an applied electric field. In yet another example, the one or more nanostructures are doped p-type. In yet another example, the one or more nano-structured volumes are contacted electrically by at least a second material. In yet another example, the one or more nano-structured volumes are further contacted electrically by a third material or by the first substrate material.

According to some embodiments, a thermoelectric device includes one or more n-type doped nano-structures and one or more p-type doped nano-structures. According to certain embodiments, a thermoelectric device includes one or more n-type doped nano-structures and one or more p-type doped nano-structures, and the one or more n-type doped nano-structures and the one or more p-type doped nano-structures are located side-by-side within a substrate. For example, a thermally induced electric current flows through one or more n-type legs with the one or more n-type doped nano-structures and through one or more p-type legs with the one or more p-type doped nanostructures, alternately.

Although specific embodiments of the present invention have been described, it will be understood by those skilled in the art that there are other embodiments that are equivalent to the described embodiments. Accordingly it is to be understood that the invention is not to be limited by the specific illustrated embodiments.

1. A uniwafer device for thermoelectric applications, the device comprising:
one or more first thermoelectric elements comprising a first patterned portion of a substrate material, each of the one or more first thermoelectric elements configured to be functionalized as an n-type semiconductor with a thermoelectric figure of merit ZT of 0.2 and greater; and
one or more second thermoelectric elements comprising a second patterned portion of the substrate material, the second patterned portion being separated from the first patterned portion by an intermediate region, each of the one or more second thermoelectric elements configured to be functionalized as a p-type semiconductor with a thermoelectric figure of merit ZT of 0.2 and greater;
wherein the one or more first thermoelectric elements and the one or more second thermoelectric elements are spatially configured to allow formation of a first contact region and a second contact region respectively connecting to each of the one or more first thermoelectric elements and/or each of the one or more second thermoelectric elements to form a continuous electric circuit.

2. The device of claim 1 wherein the substrate material comprises a first combination of material elements selected from a group consisting of Si, Ge, C, Mg, Al, Ni, Fe, W, Ti, Bi, Te, Pb, Ag, Au, Cs, Ca, O, Co, Cr, B, P, As, Sr, and Na.

3. The device of claim 1 wherein the first patterned portion comprises a second combination of material elements functionalized as n-type semiconductors selected from a group consisting of Si, Ge, C, Mg, Al, Ni, Fe, W, Ti, Bi, Te, Pb, Ag, Au, Cs, Ca, O, Co, Cr, B, P, As, Sr, and Na, and the second pattered portion comprises a third combination of material elements functionalized as p-type semiconductors selected from a group consisting of Si, Ge, C, Mg, Al, Ni, Fe, W, Ti, Bi, Te, Pb, Ag, Au, Cs, Ca, O, Co, Cr, B, P, As, Sr, and Na.

4. The device of claim 1 wherein:
the one or more first thermoelectric elements are configured to be electrically coupled to each other in series, or in parallel, or in combination of both;
the one or more second thermoelectric elements are configured to be electrically coupled to each other in series, or in parallel, or in combination of both; and
one or all of the one or more first thermoelectric elements is configured to be electrically coupled to one or all of the one or more second thermoelectric elements in series and thermally in parallel.

5. The device of claim 1 wherein each of the one or more first thermoelectric elements and the one or more second thermoelectric elements comprises a nano-structure.

6. The device of claim 5 wherein the nanostructure comprises a morphology selected from a group consisting of zero-dimensional (0D) dots, one-dimensional (1D) wires, two-dimensional (2D) ribbons, and three-dimensional (3D) networks, and combinations thereof.

7. The device of claim 1 wherein the first contact region and the second contact region respectively comprises a first electric conductor configured to form a thermal contact with a first external object and a second electric conductor configured to form a thermal contact with a second external object.

8. The device of claim 7 wherein the first electric conductor and the second electric conductor respectively comprise a third patterned portion of the substrate material and a fourth patterned portion of the substrate material.

9. The device of claim 7 wherein the first electric conductor and the second electric conductor respectively comprise a portion of the first external object and a portion of the second external object.

10. The device of claim 7 wherein the first electric conductor and the second electric conductor respectively are located either on a same side of the substrate material or on an opposite side of the substrate material.

11. The device of claim 7 wherein the continuous electric circuit is configured to draw an induced electric current as the first external object and the second external object are subjected to one or more temperature gradients.

12. The device of claim 7 wherein the continuous electric circuit is configured to supply a control electric current for inducing a heat transfer between the first external object and the second external object.

13. The device of claim 1 wherein the intermediate region comprises the substrate material reconfigured to have a thermal conductivity of about 10 W/m·K and smaller for isolating the first patterned portion and the second patterned portion.

14. The device of claim 1 wherein the intermediate region comprises a conductive material configured to couple at least two terminals of each of the one or more first thermoelectric elements and respectively two terminals of each of the one or more second thermoelectric elements.

15. A method of making a uniwafer thermoelectric device, the method comprising:
providing a substrate of material having a front surface region and a back surface region;
processing at least a portion of the substrate of material to have a thermoelectric figure of merit parameter ZT of 0.2 and greater;
patterning the portion of the substrate of material to form one or more first regions and one or more second regions separated by an intermediate region;
processing the one or more first regions bearing an n-type semiconductor characteristic;
processing the one or more second regions bearing a p-type semiconductor characteristic; and
configuring the one or more first regions and the one or more second regions to allow formations of a first contact region and a second contact region to interconnect electrically with the one or more first regions and the one or more second regions such that a continuous electric circuit is formed within the portion of the substrate material, the first contact region and the second contact region being respectively associated with at least one of the front surface region and the back surface region.

16. The method of claim 15 wherein the substrate of material comprises a combination of elements selected from a group consisting of Si, Ge, C, Mg, Al, Ni, Fe, W, Ti, Bi, Te, Pb, Ag, Au, Cs, Ca, O, Co, Cr, B, P, As, Sr, or Na.

17. The method of claim 15 wherein the processing at least the portion of the substrate of material comprises alloying of material elements, nanostructuring the portion of substrate of material, modifying electronic band structure of the portion of substrate of material to enhance the thermoelectric figure of merit parameter ZT.

18. The method of claim 15 wherein the patterning at least the portion of the single substrate of material comprises using a printing technique selected from imprinting, masking, beam illuminating, lithography, chemical etching, ion-etching, depositing, and roll-to-roll processing.

19. The method of claim 18 wherein the one or more first regions and the one or more second regions respectively comprise a first plurality of nanostructures and a second plurality of nanostructures arranged within the substrate of material.

20. The method of claim 19 wherein each of the first plurality of nanostructures and the second plurality of nanostructures comprises a morphology selected from the group consisting of zero-dimensional (0D) dots, one-dimensional (1D) wires, two-dimensional (2D) ribbons, and three-dimensional (3D) networks, and combinations thereof.

21. The method of claim 19 wherein the processing the one or more first/second regions comprises doping the substrate of material spatially within the first/second plurality of nanostructures with one or more n-/p-type dopants.

22. The method of claim 19 further comprising processing the intermediate regions within the portion of the substrate material either to be at least partially characterized as a thermal insulator with a conductivity of about 10 W/m·K and smaller or to be partially characterized as an interconnect between each of the first plurality of nanostructures and the second plurality of nanostructures.

23. The method of claim 19 wherein the configuring comprises,
determining a spatial configuration of the first plurality of nanostructures and the second plurality of nanostructures;
removing the substrate of material partially from at least one of the front surface region and the back surface region to reveal the first plurality of nanostructures and the second plurality of nanostructures within the substrate of material;
using a first patterned conductor to associate with the first contact region for interconnecting the first plurality of nanostructures and the second plurality of nanostructures according the spatial configuration;
using a second patterned conductor to associate with the second contact region for interconnecting the first plurality of nanostructures and the second plurality of nanostructures according the spatial configuration; and
isolating the first contact region substantially from the second contact region thermally.

24. The method of claim 15 wherein further comprising forming two external electric leads to the continuous electric circuit for outputting electric power as the first contact region and the second contact region respectively form a thermal contact with two external objects having a temperature gradient.

25. The method of claim 24 further comprising applying voltage across the two external electric leads for inducing a thermal energy transfer between the two external objects having the thermal contacts respectively via the first contact region and the second contact region.

26. A uniwafer device for thermoelectric application, the device comprising:
a plurality of thermoelectric elements comprising a portion of material within a single substrate having a front surface region and a back surface region, the portion of material being functionalized with a thermoelectric figure of merit ZT of 0.2 and greater, the plurality of thermoelectric elements being spatially arranged with one or more n-type semiconductor regions and one or more p-type semiconductor regions separated by an intermediate region as partially thermal isolator and partially electric interconnect;
a first patterned electrode overlying the front surface region to electrically interconnect with each of the plurality of thermoelectric elements in a first configuration; and
a second patterned electrode at least partially overlying the back surface region to electrically interconnect with each of the plurality of thermoelectric elements in a second configuration, the second configuration and the first configuration being combined to form a continuous electric circuit within the single substrate connecting the plurality of thermoelectric elements.

27. The device of claim 26 wherein each of the one or more n-type semiconductor regions and the one or more p-type semiconductor regions comprises a nano-structured volume of the single wafer of material characterized by a low thermal conductivity of about 10 W/m·K and smaller.

28. The device of claim 27 wherein the nano-structured volume of the single wafer of material comprises a morphology selected from the group consisting zero-dimensional (0D) morphologies, one-dimensional (1D) morphologies, two-dimensional (2D) morphologies, three-dimensional (3D) morphologies, and combinations thereof.

29. The device of claim 28 wherein the 1D wire morphologies comprises a plurality of nanowire structures aligned substantially vertical from a vicinity of the front surface region to a vicinity of the back surface region.

30. The device of claim 28 wherein the 2D ribbon morphologies comprises a plurality of nanoribbon structures aligned substantially parallel to the front/back surface region.

31. The device of claim 26 wherein the first patterned electrode and the second patterned electrode are configured to respectively form thermal contacts with two external objects having a temperature gradient for inducing an electric current within the continuous electric circuit.

32. The device of claim 26 further comprising a pair of external leads of the continuous electric circuit, the pair of external leads being configured to receive an external control voltage for inducing a thermal energy transfer between the front surface region and the back surface region through thermal contacts respectively with the first patterned electrode and the second patterned electrode.
